(19) United States
(12) Patent Application Publication
(10) Pub. No.: US 2017/0170218 A1
(43) Pub. Date: Jun. 15, 2017

(54) TOP GATE METAL OXIDE THIN FILM TRANSISTOR SWITCHING DEVICE FOR IMAGING APPLICATIONS

(71) Applicant: DPIX, LLC, Colorado Springs, CO (US)

(72) Inventors: Jungwon Park, Colorado Springs, CO (US); Karthik Nagarajan, Colorado Springs, CO (US); Byung-Kyu Park, Colorado Springs, CO (US); Shawn Michael O'Rourke, Colorado Springs, CO (US)

(21) Appl. No.: 15/344,335

(22) Filed: Nov. 4, 2016

Related U.S. Application Data
(60) Provisional application No. 62/386,682, filed on Dec. 9, 2015.

(51) Int. Cl. H01L 27/146; H01L 27/30; H01L 29/786

(52) U.S. Cl. CPC H01L 27/14616; H01L 29/7869; H01L 27/14658; H01L 27/14636; H01L 27/14689; H01L 27/14692; H01L 27/307; H01L 27/14634

(57) ABSTRACT

A method of manufacturing an image sensor device includes providing a substrate; forming a buffer layer on the substrate; forming a metal oxide channel on the buffer layer; forming a gate oxide layer on the buffer layer and the metal oxide channel; forming a gate metal layer on the gate oxide layer; forming a photodiode stack on the gate metal layer; patterning the gate oxide layer and the gate metal layer to form a first portion under the photodiode stack, and a second portion comprising a transistor; forming an interlayer dielectric layer over at least the photodiode stack and the transistor; forming a plurality of vias in the interlayer dielectric layer; and metalizing the vias to form contacts to the image sensor device.

### RELATED APPLICATIONS

The present application relates to and claims priority of U.S. provisional patent application (“Copending Provisional Application”), Ser. No. 62/386,682, filed on Dec. 9, 2015. The disclosure of the Copending Provisional Application is hereby incorporated by reference in its entirety.

### BACKGROUND OF THE INVENTION

1. Field of the Invention

The present invention generally relates to image sensor devices, and, more particularly, to a method for manufacturing the image sensor devices.

2. Relevant Background

Image sensor devices are known in the art. A subset of image sensor devices can be used, for example, as a flat panel imager for use in X-ray imaging (digital radiography). While top-gate and bottom-gate device structures are known in the art that are suitable for use in the image sensor device, further performance improvements in, for example, X-ray imaging, are always demanded by the medical industry. Performance improvements will result in greater resolution of the X-ray images, which will allow professionals in the medical industry to better carry out their life-saving work.

### SUMMARY OF THE INVENTION

Transparent metal oxide semiconductor material has been used for the channel layer of a thin film transistor (“TFT”) due to its fast switching speed. A top gate switching device structure according to the present invention is described due to its relatively simple process flow and lower processing costs when compared to a conventional bottom-gate silicon-based detector device. An integration scheme according to the present invention combines a top gate structure with a transparent metal oxide semiconductor material. For display applications, a bottom gate amorphous silicon TFT structure has been used widely due to its good electrical behavior. However, adopting metal oxide as the TFT channel material, the top gate metal oxide switching is fabricated by a lower number of mask process steps than a conventional backplane process. Further, the structure of the present invention exhibits lower switching overlap capacitance features that reduce the overall data line capacitance for the whole device. In turn, this results in a lower noise device, which is important for medical applications.

The present invention provides a method for fabricating a flat panel device for medical applications, including at least X-ray imaging. A fabrication process for a metal oxide based switching device is disclosed, wherein either an inorganic or organic photodiode can be used for X-ray detection applications.

The conventional medical application backplane for a flat panel array or image sensor device is usually comprised of an amorphous silicon based switching device and an amorphous silicon photodiode. Even though amorphous silicon has lower field-effect mobility than a polycrystalline silicon based switching device, it has been widely used in the display industry as well as the medical application device industry. One reason for this is low fabrication cost. Since low temperature polycrystalline silicon (“LTPS”) has a higher fabrication cost, it requires an anneal tool to achieve a poly-crystalline, or expensive silicon/quartz substrate, and an implantation tool to acquire ohmic contact between data line metal and the channel material. Another reason is that LTPS has a higher leakage current than an amorphous silicon process. Since LTPS needs a top-gated structure only due to its anneal process, which makes an amorphous silicon phase to a polycrystalline phase, it is inevitable to break the vacuum between the channel silicon and the gate dielectric material. In turn, this results in a higher trap density at the interface. Trap density at the interface is a major source of leakage current of silicon based top-gate switching devices. Another source is the grain boundaries of the LTPS. Grain boundaries are in the nature of polycrystalline silicon. It acts as a leakage source for LTPS based switching devices. Therefore, transparent metal oxide (whose composition usually includes Indium, Zinc, Gallium, Hafnium, Aluminum, as well as other elements and components) material is a good candidate to overcome the current silicon (both amorphous and LTPS) based switching devices. The wider band gap of metal oxide makes it possible to consider both bottom-gate and top-gate structures. However, a bottom-gate structure metal oxide device will have an overlap capacitance between the gate metal electrode and the data metal electrode. Further, it needs a channel passivation layer to protect the channel to improve the device reliability for medical applications. The bottom-gate structure has inevitable structural disadvantages even though back-side exposure is used during manufacturing to achieve self-aligning. A top-gate structure still needs an ohmic contact between the metal oxide channel and the source arid drain metal contacts.

Taking into account the two above concerns, a lower mask set using a top-gate structure that achieves ohmic contact without any further mask sets is presented and described according to the present invention. Forming of the metal oxide channel, gate line, data line channel, and photodiode is presented and described according to the present invention.

Firstly, a buffer dielectric film is deposited by chemical vapor deposition (“CVD”) or plasma-enhanced CVD (“PECVD”). The buffer film can be silicon dioxide, silicon nitride, silicon oxynitride, of an alumina dielectric film. Film thickness can be varied depending upon a particular application. Then, metal oxide film is deposited on the buffer film by the means of physical vapor deposition (“PVD”) or a solution based process. The metal oxide film is patterned to form the active area of the device. Following this process step, the gate dielectric material and the gate material is deposited on the patterned metal oxide film. A photodiode is formed at this step by CVD deposition of the top surface of the gate metal film. The photodiode top surface area contact is formed by Indium-Tin-Oxide (“ITO”) metal film by means of sputtering (PVD). A second mask process is used to pattern the photodiode. A third mask process is applied to pattern a gate electrode, gate dielectric area, and the bottom electrode of the photodiode. The gate metal film, and the gate dielectric film are etched by a wet or dry etch method, and at the end of this etching step, additional treatment can be applied by using inert gas based plasma treatments. The inert gas can be helium or argon, or other inert gasses or combinations of gasses. By using radical bombardment of the surface of the metal oxide, various conducting characteristics are achievable. The semiconducting channel area is protected by the gate area. The channel and ohmic contact area is reserved by means of an additional treatment scheme. To passivate the patterned photodiode and channel thin film transistor area, a dielectric film is deposited. A fourth mask process is used to pattern the dielectric film to form a source/drain electrode/line, and a bias electrodeline. A fifth mask process is used to pattern a metal film on the dielectric film. According to the method of the present invention, there is no overlap area on the thin film transistor. The method of the present invention reduces data line capacitance when compared to a conventional bottom-gate TFT structure. Further, the method of the present invention eliminates one mask step for the ohmic contact layer deposition/implantation and pattern step. A further dielectric film is deposited on the overall device to passivate the whole device to prevent reactions from the outside environment. Finally, a sixth mask process is to pattern contact pads to make a contact to read out devices.

The image sensor device and method of manufacturing is fully described below with various embodiments and examples, and is illustrated in the following drawings.

### BRIEF DESCRIPTION OF THE DRAWINGS

FIGS. 1-6 illustrate, in cross-sectional views, a manufacturing method for an image sensor device according to the present invention including a photodiode and a transistor; and

FIG. 7 is a pixel circuit that corresponds to the image sensor device shown in FIGS. 1-6.

### DETAILED DESCRIPTION OF THE PREFERRED EMBODIMENTS

A manufacturing process for an image sensor device performed is illustrated with respect to FIGS. 1-6.

Referring to FIG. 1, a buffer dielectric film 104 is deposited on a substrate 102 using PECVD. A metal oxide channel film 106 is deposited by a PVD system and patterned using a photolithography process. Substrate 102 can comprise a glass, plastic, metal foil, or silicon substrate. The buffer layer 104 can comprise a silicon dioxide, silicon nitride, silicon oxynitride, or alumina dielectric film. The metal oxide channel 106 can comprise a patterned Indium oxide (whose composition varies, but major composition components are Indium, Zinc, Gallium, Hafnium, Aluminum, or Indium-Zinc-Gallium-Oxide (IGZO)) layer.

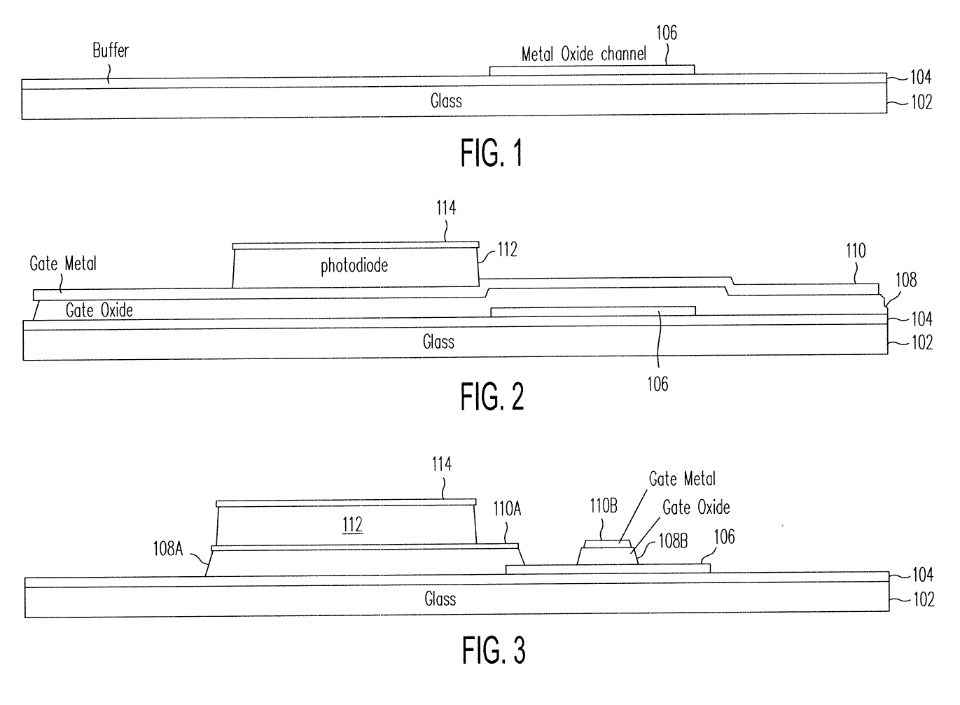

Referring to FIG. 2, a gate oxide layer 108, a gate metal layer 110, a photodiode stack film including photodiode layer 112 and top contact layer 114 are deposited using PECVD and PVD. The photodiode layers 112 and 114 are patterned using an etch process. The gate oxide layer 108 can comprise a silicon dioxide, silicon nitride, silicon oxynitride, or alumina layer. The gate metal layer 110 can comprise an Aluminum, Titanium, Molybdenum, Tungsten, or Chromium layer. The photodiode 112 of the photodiode stack can comprise a Silicon, or organic photodiode. The top contact 114 of the photodiode stack can comprise a transparent metal such as Indium-Zinc-Oxide (IZO) or Indium-Tin-Oxide (ITO) top contact.

Referring to FIG. 3, the gate metal layer 110 and gate oxide layer 108 are patterned and etched to form a photodiode portion 108A and 110A, and a transistor portion 108B and 110B. Either a wet or a dry etch process, or both, can be used. Additional treatments are applied to achieve ohmic contact areas. The semiconductor channel 106 is protected by the gate metal area 110B.

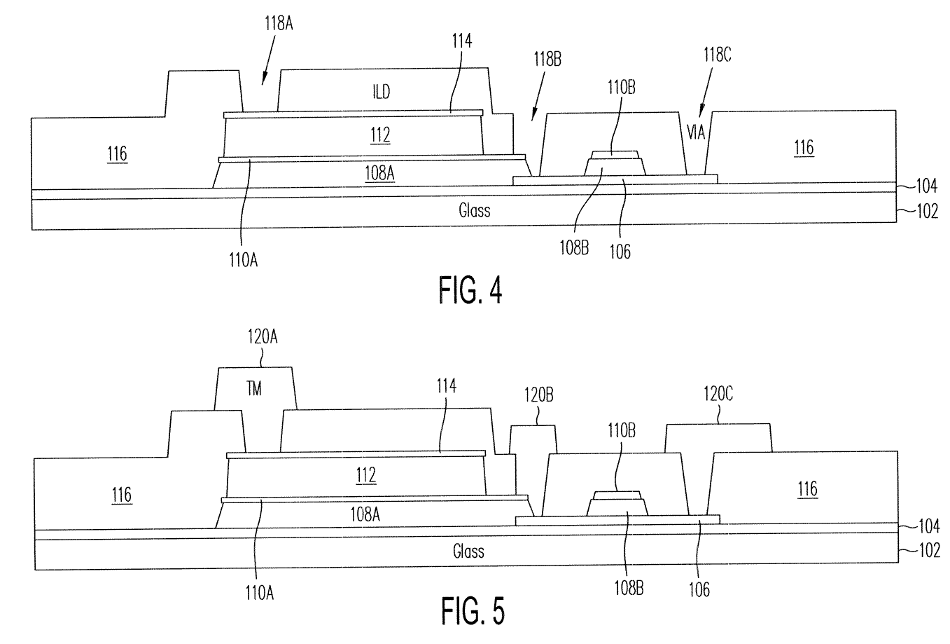

Referring to FIG. 4, an interlayer dielectric film 116 is deposited and vias 118A, 118B, and 118C are patterned and etched. The interlayer dielectric layer 116 can comprise a silicon dioxide, silicon nitride, silicon oxynitride, or alumina layer.

Referring to FIG. 5, a top metal layer 120 is deposited and patterned to form power and bias lines 120A and 120C, and data line 120B. Metalizing the vias 118A, 118B, and 118C comprises metalizing the vias with an Aluminum, Titanium, Molybdenum, Tungsten, or Chromium metal layer.

Referring to FIG: 6, a passivation dielectric layer 122 is deposited and vias are opened at the periphery of the sensor array to make contacts between the pixel devices and the peripheral circuitry of the sensor array. The passivation layer 122 can comprise a silicon dioxide, silicon nitride, silicon oxynitride, or alumina layer.

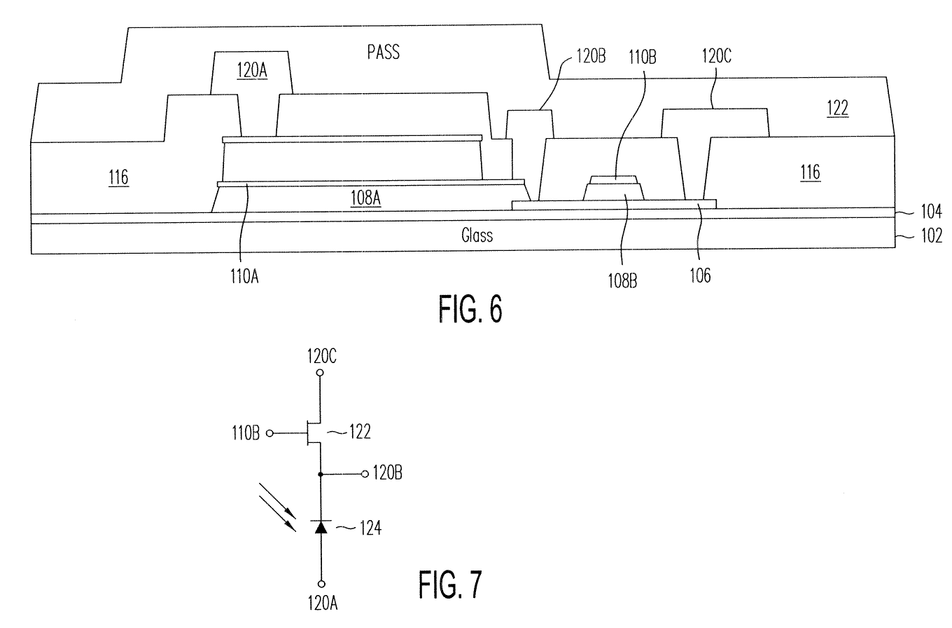

Referring to FIG. 7, a passive pixel circuit is shown corresponding to the device shown in FIG. 6. A transistor 122 is coupled between nodes 120C, 110B, and 120B. A photodiode 124 is coupled between nodes 120B and 120A.

Although the invention has been described and illustrated with a certain degree of particularity, it is understood that the present disclosure has been made only by way of example, and that numerous changes in the combination and arrangement of parts can be resorted to by those skilled in the art without departing from the spirit and scope of the invention, as hereinafter claimed.

We claim:

1. A method of manufacturing an image sensor device comprising:
providing a substrate;
forming a buffer layer on the substrate;
forming a metal oxide channel on the buffer layer;
forming a gate oxide layer on the buffer layer and the metal oxide channel;
forming a gate metal layer on the gate oxide layer;
forming a photodiode stack on the gate metal layer;
patterning the gate oxide layer and the gate metal layer to form a first portion under the photodiode stack, and a second portion comprising a transistor;
forming an interlayer dielectric layer over at least the photodiode stack and the transistor;
forming a plurality of vias in the interlayer dielectric layer; and
metalizing the vias to form contacts to the image sensor device.

2. The method of claim 1, wherein providing the substrate comprises providing a glass substrate.

3. The method of claim 1, wherein forming the buffer layer comprises forming a silicon dioxide, silicon nitride, silicon oxynitride, or alumina dielectric film.

4. The method of claim 1, wherein forming the metal oxide channel comprises forming a patterned Indium oxide layer.

5. The method of claim 1, wherein forming the gate oxide layer comprises forming a silicon dioxide, silicon nitride, silicon oxynitride, or alumina layer.

6. The method of claim 1, wherein forming the gate metal layer comprises forming an Aluminum, Titanium, Molybdenum, Tungsten, or Chromium layer.

7. The method of claim 1, wherein forming the photodiode stack comprises forming a Silicon or organic photodiode.

8. The method of claim 1, wherein forming the photodiode stack comprises forming a transparent metal top contact.

9. The method of claim 1, wherein forming the interlayer dielectric layer comprises forming a silicon dioxide, silicon nitride, silicon oxynitride, or alumina layer.

10. The method of claim 1, wherein metalizing the vias comprises metalizing the vias with an Aluminum, Titanium, Molybdenum, Tungsten, or Chromium layer.

11. An image sensor device comprising:
a substrate;
a buffer layer on the substrate;
a metal oxide channel on the buffer layer;
a gate oxide layer on the buffer layer and the metal oxide channel;
a gate metal layer on the gate oxide layer;
a photodiode stack on the gate metal layer;
the gate oxide layer and the gate metal layer forming a first portion under the photodiode stack, and a second portion comprising a transistor;
an interlayer dielectric layer over at least the photodiode stack and the transistor; and
a plurality of metalized vias in the interlayer dielectric layer comprising contacts to the image sensor device.

12. The image sensor device of claim 11, wherein the substrate comprises a glass substrate.

13. The image sensor device of claim 11, wherein the buffer layer comprises a silicon dioxide, silicon nitride, silicon oxynitride, or alumina dielectric film.

14. The image sensor device of claim 11, wherein the metal oxide channel comprises a patterned Indium oxide layer.

15. The image sensor device of claim 11, wherein the gate oxide layer comprises a silicon dioxide, silicon nitride, silicon oxynitride, or alumina layer.

16. The image sensor device of claim 11, wherein the gate metal layer comprises an Aluminum, Titanium, Molybdenum, Tungsten, or Chromium layer.

17. The image sensor device of claim 11, wherein the photodiode stack comprises a Silicon, or Organic photodiode.

18. The image sensor device of claim 11, wherein the photodiode stack comprises a transparent metal top contact.

19. The image sensor device of claim 11, wherein the interlayer dielectric layer comprises a silicon dioxide, silicon nitride, silicon oxynitride, or alumina layer.

20. The image sensor device of claim 11, wherein the metalized vias comprise an Aluminum, Titanium, Molybdenum, Tungsten, or Chromium metal layer.
